(19) United States
(12) Patent Application Publication
(10) Pub. No.: US 2006/0261433 A1
(43) Pub. Date: Nov. 23, 2006

(54) Nanotube Schottky diodes for high-frequency applications

(76) Inventors: Harish Manohara, Arcadia, CA (US); Brian Hunt, LaCrescenta, CA (US); Erich Schlecht, Pasadena, CA (US); Peter Siegel, LaCanada, CA (US); Eric Wong, Los Angeles, CA (US)

Correspondence Address: TOPE-MCKAY & ASSOCIATES, 23852 PACIFIC COAST HIGHWAY #311, MALIBU, CA, 90265, US

(21) Appl. No.: 11/439,625

(22) Filed: May 23, 2006

Related U.S. Application Data
(60) Provisional application No. 60/683,825, filed on May 23, 2005.

(51) Int. Cl. H01L 21/00

(52) U.S. Cl. 257/471; 438/92

(57) ABSTRACT

Described is a Schottky diode using semi-conducting single-walled nanotubes (s-SWNTs) with titanium Schottky and platinum Ohmic contacts for high-frequency applications. The diodes are fabricated using angled evaporation of dissimilar metal contacts over an s-SWNT. The devices demonstrate rectifying behavior with large reverse-bias breakdown voltages of greater than −15 V. In order to decrease the series resistance, multiple SWNTs are grown in parallel in a single device, and the metallic tubes are burnt-out selectively. At low biases, these diodes showed ideality factors in the range of 1.5 to 1.9. Modeling of these diodes as direct detectors at room temperature at 2.5 terahertz (THz) frequency indicates noise equivalent powers (NEP) comparable to that of the state-of-the-art gallium arsenide sold-state Schottky diodes, in the range of 10-13 W/square-root (√) Hz.

### PRIORITY CLAIM

The present application is a non-provisional application, claiming the benefit of U.S. Provisional Application No. 60/683,825, filed on May 23, 2005, titled, “Carbon Nanotube Schottky Diodes for High Frequency Applications.”

### GOVERNMENT RIGHTS

The invention described herein was made in the performance of work under a NASA contract and is subject to the provisions of Public Law 96-517 (35 USC 202) in which the Contractor has elected to retain title.

### FIELD OF INVENTION

The present invention relates to Schottky diodes, and more particularly, to Schottky diodes using semi-conducting single-walled nanotubes (s-SWNTs) with dissimilar contacts for high-frequency applications.

### BACKGROUND OF INVENTION

For high-frequency applications in the range of 30 gigahertz (GHz) to 3 terahertz (THz), (i.e., microwave to sub-millimeter wave region), diodes are of particular interest as detectors, mixers, and frequency multipliers. In particular, solid-state Schottky diodes (rectifying metal-semiconductor junctions) are employed because of their higher switching speeds and their inherent suitability for low-voltage, high-current applications. The state-of-the-art utilizes solid-state Schottky diode detectors for room temperature sensor systems and Schottky diode multipliers for sub-millimeter wave power generation. However, above a few hundred GHz, the inherent parasitic capacitance (proportional to semiconductor junction area) and resistance (inversely proportional to electron mobility) of these devices severely limit the achievable sensitivity for detection, (direct detector noise equivalent power (NEP)˜10⁻¹² W/square-root (√) Hz, heterodyne NEP˜10⁻¹⁷ W/√Hz for cooled operation at 4 K), and generated power at THz frequencies (generally only microwatts of power up to 1.5 THz). Such limitations are due, in part, because of the limitations of the fabrication process and the material properties. From the material point of view, carbon nanotubes offer an excellent alternative to their solid-state counterparts because of their small junction areas due to their physical dimensions (<1 to 2 nm diameter), high electron mobilities (up to 200,000 cm²/Vs as reported in the art) and low estimated capacitances (tens of aF/μm), leading to predicted cut-off frequencies in the THz range.

The electronic properties of single-walled carbon nanotubes (SWNTs) have been studied in detail. The synthesis of SWNTs results in tubes that are either metallic (m-SWNTs) or semiconducting (s-SWNTs) depending on their chirality. Semiconducting SWNTs typically exhibit p-type conductivity for measurements done in the air. Earlier studies have employed s-SWNTs to develop Schottky-barrier-contact field effect transistors (FETs) and to rectify junctions based on carbon nanotube (CNT) defects, double gates, or crossed m- and s-SWNTs. Others have studied in detail, the AC response of s-SWNT-FETs using phenomenological models and through measurements at 2.6 GHz. Interestingly, a significantly decreased AC impedance (when compared to DC impedance) of the device (at 4 K) has been shown, resulting from of a possible capacitive coupling between the nanotube and the contact pads. In fact, in m-SWNT circuits, studies have measured AC impedances (˜1.7 kΩ) much lower than the quantum limited resistance for a one-dimensional (1-D) system (h/4e²˜6.25 kΩ, where h is Planck's constant and e is the charge of an electron). While, this is encouraging, a further reduction in parasitics that hinder the AC performance of an electronic device can be achieved by employing a Schottky diode design in which a substrate-less membrane architecture can be employed similar to an earlier reported monolithic membrane diode (MoMED) design for a 2.5 THz receiver system. A theoretical study concluded that unlike in planar junction Schottky diodes, the Fermi level pinning in carbon nanotube Schottky diodes does not control the device properties and, as a result, the threshold may be tuned for optimal device performance. The theoretical study showed that for these devices, the Schottky barrier height is controlled by the metal work function, unaffected by the Fermi level pinning, which offers the possibility of controlling the barrier height by the choice of the metal.

However, nothing previously devised has incorporated nanotubes into a Schottky diode. Thus, a continuing need exists for a Schottky diode using a nanotbue that maintains performance at frequencies above 500 GHz.

### SUMMARY OF INVENTION

The present invention relates to a nanotube Schottky diode. The nanotube Schottky diode comprises a nanotube formed of a semi-conductive material. A first conductive contact is attached with the nanotube. Additionally, a second conductive contact is attached with the nanotube. The first conductive contact and the second conductive contact are formed of dissimilar materials and each of the conductive contacts is attached with the nanotube such that they are separated.

In one aspect, the first conductive contact is formed of a material that has a lower work function than that of the nanotube to form a Schottky contact and the second conductive contact is formed of a material that has a higher work function than that of the nanotube to form an Ohmic contact.

In yet another aspect, the present invention further comprises a substrate with an insulating layer formed on the substrate. The nanotube is attached with the insulating layer.

In another aspect, the nanotube has a length with two ends and the first conductive contact is attached proximate one of the two ends of the nanotube while the second conductive contact is attached proximate the other of the two ends of the nanotube.

Additionally, the Schottky contact is formed of at least one material selected from a group consisting of titanium and aluminum. Further, the Ohmic contact is formed of at least one material selected from a group consisting of platinum and palladium.

In another aspect, each of the conductive contacts further comprises a contact pad attached with the conductive contact.

In yet another aspect, the substrate is formed of silicon and the insulating layer is formed of at least one material selected from a group consisting of silicon dioxide and silicon nitride.

In another aspect, each of the conductive contacts includes an axis that is approximately parallel to the other axis and that runs approximately perpendicular to the nanotube. The substrate is etched-out as an etched-out portion between each of the axes, such that the insulating layer and the nanotube span across the etched-out portion. In another aspect, a gap exists in the substrate and in the insulating layer between each of the axes, such that the nanotube is suspended across and bridges the gap.

Furthermore, the nanotube is a single-walled carbon nanotube, or in another aspect, a multi-walled carbon nanotube.

In another aspect, the present invention comprises a method for forming the nanotube Schottky diode described herein. Finally, the present invention includes a diode produced by the aforementioned method.

### BRIEF DESCRIPTION OF THE DRAWINGS

The objects, features and advantages of the present invention will be apparent from the following detailed descriptions of the various aspects of the invention in conjunction with reference to the following drawings, where:

FIG. 1A is an illustration of the single-walled nanotube (SWNT) Schottky diode according to the present invention;

FIG. 1B is an illustration of a SWNT Schottky diode as formed through brute-force lithographic metal patterning, according to the present invention;

FIG. 1C is an illustration of a membrane carbon nanotube (CNT) Schottky diode according to the present invention;

FIG. 1D is an illustration of a suspended CNT bridge Schottky diode according to the present invention;

FIG. 2 is a process schematic illustrating the fabrication of a SWNT Schottky diode by depositing dissimilar metals (e.g., Titanium and Platinum) as the Schottky and the Ohmic contacts respectively through angled evaporation, resulting in the Schottky diode depicted in FIG. 1A;

FIG. 3 is a chart illustrating the DC (current-voltage) I-V characteristics of four different SWNT-Schottky devices fabricated on the same substrate in the same run (with zero gate voltage), where all the devices have a single s-SWNT bridging the gap between contact pads;

FIG. 4 is a chart illustrating the DC I-V characteristic of a SWNT-Schottky device with multiple SWNTs bridging the gap between the contact pads;

FIG. 5 is a chart illustrating ideality curve fits in a low bias range for device d1-II (with single s-SWNT) and device d2-II (with multiple s-SWNTs) Schottky diodes; and

FIG. 6 is a chart illustrating the dependence of the voltage responsivity (β_{V}), the noise equivalent power (NEP), and the cut-off frequency (f_{C}) on the series resistance of a hypothetical 100-nanotube SWNT-Schottky diode.

### DETAILED DESCRIPTION

The present invention relates to Schottky diodes and, more particularly, to Schottky diodes using semi-conducting single-walled nanotubes (s-SWNTs) with dissimilar contacts (e.g., a titanium Schottky contact and a platinum Ohmic contact) for high-frequency applications. The following description is presented to enable one of ordinary skill in the art to make and use the invention and to incorporate it in the context of particular applications. Various modifications, as well as a variety of uses in different applications will be readily apparent to those skilled in the art and the general principles defined herein may be applied to a wide range of embodiments. Thus, the present invention is not intended to be limited to the embodiments presented, but is to be accorded the widest scope consistent with the principles and novel features disclosed herein.

In the following detailed description, numerous specific details are set forth in order to provide a more thorough understanding of the present invention. However, it will be apparent to one skilled in the art that the present invention may be practiced without necessarily being limited to these specific details. In other instances, well-known structures and devices are shown in block diagram form, rather than in detail, in order to avoid obscuring the present invention.

The reader's attention is directed to all papers and documents which are filed concurrently with this specification and which are open to public inspection with this specification, and the contents of all such papers and documents are incorporated herein by reference. All the features disclosed in this specification, (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

Furthermore, any element in a claim that does not explicitly state “means for” performing a specified function, or “step for” performing a specific function, is not to be interpreted as a “means” or “step” clause as specified in 35 U.S.C. Section 112, Paragraph 6. In particular, the use of “step of” or “act of” in the claims herein is not intended to invoke the provisions of 35 U.S.C. 112, Paragraph 6.

Before describing the invention in detail, a description of various principal aspects of the present invention is provided. Subsequently, an introduction provides the reader with a general understanding of the present invention. Finally, details of the invention are presented to give an understanding of the specific aspects.

(1) Principal Aspects

The present invention has two “principal” aspects. The first is a Schottky diode having a nanotube and dissimilar contacts for use in high-frequency applications. The second principal aspect is a method for forming the Schottky diode. These aspects will be described in more detail below.

(2) Introduction

The present invention comprises Schottky diodes created by depositing two dissimilar conductive materials (e.g., metals) at the two ends of p-type s-single-walled carbon nanotubes (SWNTs). One of the metals has a lower work function (Φ) than that of the SWNT (Φ_{NT}˜4.9 eV) to make a Schottky contact and the other metal has a higher Φ than that of the SWNT to make an Ohmic contact. The present invention also includes a method for forming the Schottky diodes. The performances of these diodes as detectors at high-frequencies is shown below by calculating their voltage responsivity and noise equivalent power (NEP) using analytical models.

(4) Details of the Invention

As described above, the present invention relates to a Schottky diode having a nanotube connecting two dissimilar metals. For clarity, various versions of the nanotube Schottky diode will be described first. Second, methods for forming the Schottky diodes will be described. Third, experimental results using a Schottky diode are provided.

(4.1) Nanotube Schottky Diodes

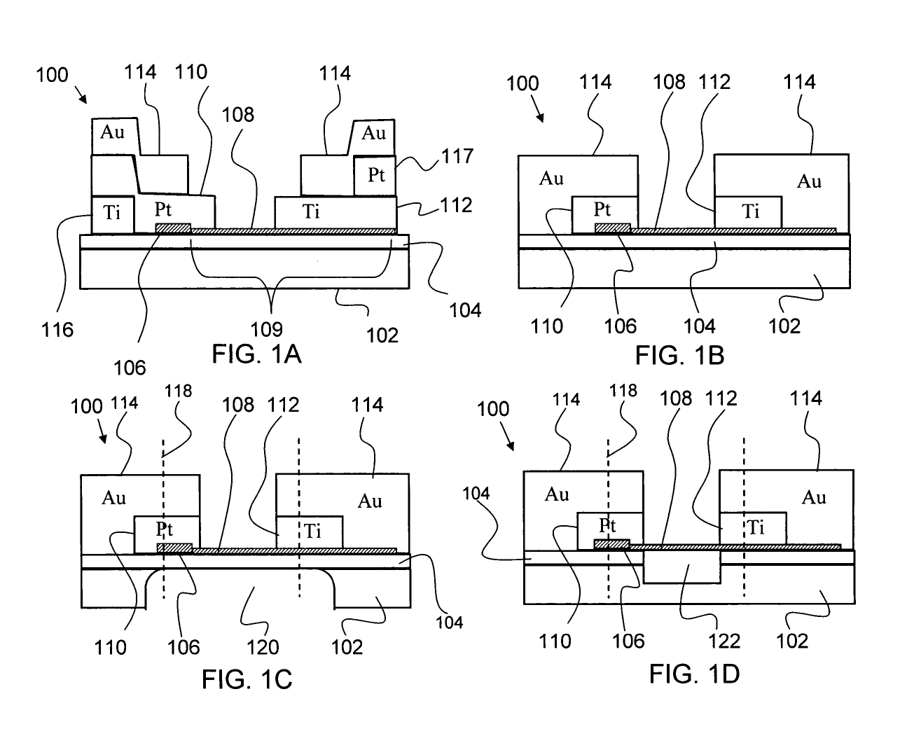

As shown in FIGS. 1A through 1D, the present invention is a Schottky diode 100. The Schottky diode 100 includes a substrate 102 with an insulating layer 104. The substrate 102 is formed of any suitably stable material, a non-limiting example of which includes silicon. Additionally, the insulating layer 104 is formed of any suitably insulating material, non-limiting examples of which include silicon dioxide and silicon nitride.

Using a catalyst 106, a nanotube 108 is grown on the insulating layer 104, with the resulting nanotube 108 having a certain length 109 and two opposing ends. Two contacts of dissimilar conductive materials (e.g., metals) are formed on the nanotube 108 with a gap therebetween. In one non-limiting example, one of the contacts is formed proximate one of the opposing ends while the other contact is formed proximate the other opposing end. Additionally, one of the contacts is an Ohmic contact 110 while the other contact is a Schottky contact 112. An Ohmic contact is a region on a device that has been prepared so that the current-voltage (I-V) curve of the device is linear and symmetric. If the I-V characteristic is non-linear and asymmetric, the contact can instead be termed a blocking or Schottky contact.

To enable connection of various devices to the Schottky diode 100, a contact pad 114 is attached with each of the metal contacts 110 and 112. The contact pad 114 is formed of a conductive material, a non-limiting example of which includes gold (Au).

It should be noted that although the nanotube 108 has been described as being grown on a substrate (e.g., insulating layer 104) of the diode 100, the present invention is not limited thereto. As can be appreciated by one skilled in the art, the nanotube 108 can be grown separately and subsequently placed on the substrate (e.g., the spin-coated nanotubes produced by Nantero, Inc., which is located at 25-D Olympia Avenue, Woburn, Mass. 01801).

The nanotube 108 is formed of any semi-conductive material, a non-limiting example of which includes carbon. More specifically, the nanotube 108 can be a s-single-walled carbon nanotubes (SWNTs). However, as can be appreciated by one skilled in the art, multi-walled carbon nanotubes can also be used, as long as they are completely semi-conducting. Additionally, although depicted as a single nanotube 108, actual formation and usage of the nanotubes typically results in and requires multiple nanotubes. Furthermore, as stated above, although the Schottky diode 100 is illustrated for a carbon nanotube, it can be applied to any other type of semi-conducting material nanotubes or nanowires.

The material for the Schottky contact 112 is a material (e.g., metal) that has a lower work function (Φ) than that of the SWNT, non-limiting examples of which include titanium (Ti) or aluminum (Al). Alternatively, the material for the Ohmic contact 110 is a material that has a higher Φ than that of the SWNT, non-limiting examples of which include platinum (Pt) and palladium (Pd). In one non-limiting example, the choice of metals used are Ti for the Schottky contact 112 (Φ_{Ti}=4.33 eV<Φ_{NT}; ΦNT˜4.9 eV) and Pt for the Ohmic contact 110 (Φ_{Pt}=5.65 eV>Φ_{NT})

FIG. 1A illustrates a Schottky diode 100 formed through an angled evaporation technique. As shown in FIG. 1A, the angled evaporation technique results in metal deposited during formation of the Schottky contact 112 being left as a first residual metal 116 beyond the catalyst 106. Alternatively, metal deposited during formation of the Ohmic contact 110 is also left as a second residual metal 117 on the Schottky contact 112 (or vice versa). The residual metals 116 and 117 are largely inconsequential provided that they are not in contact with the nanotube 108.

FIG. 1B illustrates a Schottky diode 100 that is formed through brute-force lithographic metal patterning. In contrast to angled evaporation, the brute-force lithographic metal patterning defines the contact regions well and the metal for the Ohmic contact 110 (e.g., Pt) and the Schottky contact 112 (e.g., Ti) will be strictly restricted to their respective ends with a contact pad 114 metal (e.g., Au) deposited on each of them.

FIG. 1C illustrates a Schottky diode 100 that is formed as a membrane carbon nanotube (CNT) Schottky diode. The basic diode structure can be formed through angled evaporation, brute-force lithographic metal patterning, or any other suitable technique. Once formed, the substrate 102 is thereafter altered. Each of the metal contacts includes an axis 118 that runs approximately perpendicular to the nanotube 108. The substrate 102 is then etched-out as an etched-out portion 120 between each of the axes 118. Once the substrate 102 is etched-out, the insulating layer 104 and the nanotube 108 span across the etched-out portion 120.

FIG. 1D illustrates a Schottky diode 100 that is formed as a suspended CNT bridge Schottky diode. The Schottky diode 100 includes a gap 122 in the substrate 102 and in the insulating layer 104 between each of the axes 118. In this aspect, the nanotube 108 is suspended across, and bridges, the gap 122.

(4.2) Formation of a Schottky Diode having a Nanotube with Dissimilar Contacts

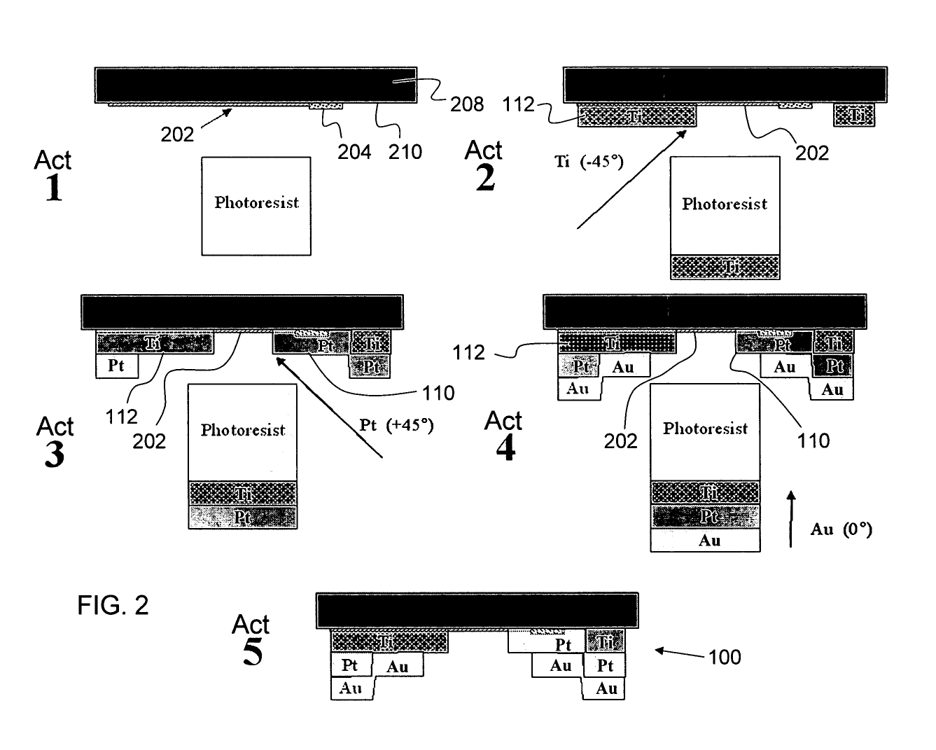

The present invention also comprises a method for forming the Schottky diodes having a nanotube with tow dissimilar contacts. Although the process described below applies primarily to the angled evaporation technique (as shown in FIG. 2), as can be appreciated by one skilled in the art, many of the steps can apply to the formation of each of the Schottky diodes described above (e.g., growing the SWNTs). Additionally, although specific measurements and devices are described below, they are used as non-limiting examples and other measurements and devices may be used to produce similar results.

As shown in FIG. 2, the metal deposition was conducted using a self-aligned angled evaporation technique to deposit both metals with a single photoresist 200 mask. Both single s-SWNT devices and multiple s-SWNT devices have been tested. For high-frequency operation, it is essential to develop these diodes with a high yield of s-SWNTs per device grown in parallel, as explained later. As shown in Act 1, the SWNTs 202 were grown using iron catalysts 204 on a silicon (Si) substrate 208 with a ˜400 nanometer (nm) thick thermal oxide layer 210. The iron nanoparticles (FeNPs) used to grow SWNTs were synthesized similarly to a previously published procedure (Hyeon, T.; Lee, S. S.; Park, J.; Chung, Y.; Na, H. B. J. Am. Chem. Soc. 2001, 123, 12798-12801).

The distribution of nanoparticle diameters was 5.8±2.0 nm as determined by transmission electron microscopy (TEM) using an Akashi EM-002b electron microscope at 100 kilovolts (kV). As described previously, monolayers of FeNPs were patterned onto oxidized silicon substrates using 350 nm thick polymethyl methacrylate (PMMA) (produced by MicroChem Corp., 950K molecular weight, 4% in chlorobenzene). MicroChem Corp. is located at 1254 Chestnut Street, Newton, Mass., 02462.

All the growths were done at 850° C. using methane (CH₄ at 1500 standard cubic centimeters per minute (sccm)) and hydrogen (H₂ at 50 sccm) at a pressure of 780 torr. The resulting SWNTs were characterized by atomic force microscopy (AFM) using a Digital Instruments (DI) Nanoscope III with silicon probes in Tapping Mode. The DI Nanoscope III is produced by Veeco Instruments, located at 112 Robin Hill Rd., Santa Barbara, Calif., 93111. The tube diameters were measured to be between 1 and 3 nm. TEM studies revealed that most of the nanotubes produced were single-walled, although there is the possibility of occasional double walled nanotubes.

The Schottky diode fabrication involved patterning the electrodes directly over the nanotubes 202 using three masking layers stacked as follows: 700 nm thick 950,000 (K) molecular weight PMMA; 15 nm thick Ti; and 1.4 micrometer (μm) thick photoresist 200, with PMMA being the bottom-most layer used to protect the nanotube 202 during further processing. The photoresist 200 was patterned to create an “isolation block” between the two opposing ends of the nanotube 202 followed by the removal of the Ti layer in CF₄/O₂ plasma. The isolation block facilitates selective coating of the ends of the nanotube 202 with dissimilar metals through angled evaporation. The electrode patterns were transferred into PMMA with ˜1 μm undercut. At this stage, the portion of the nanotube 202 (i.e., SWNT) that lies between the electrode patterns was still covered by the PMMA protective layer. Finally, as shown in Acts 2 through 4 (shown in FIG. 2), the Schottky (Ti) contact 112 and the Ohmic (Pt) contact 110 were deposited by evaporating the respective metals in series at various angles (e.g., Ti at −45°; Pt at +45°; and the last electrode layer of Au at 0° (perpendicular to the sample surface)) all in one step without breaking the vacuum. The final liftoff was done by soaking the structure in acetone to realize the SWNT Schottky device 100 (as shown in Act 5). The above process resulted in exemplary metal layer thicknesses that were as follows: Ti˜20 nm; Pt˜17 nm; and Au˜100 nm, with typical lengths of SWNTs between contact pads ranging from 1.7 to 2.5 μm.

(4.3) Exemplary Experimental Results

As can be appreciated by one skilled in the art, the experimental results herein are provided for illustrative purposes only and the invention is not intended to be limited thereto. The first set of devices produced mostly contained a single SWNT bridging the gap between the metal pads in each device. As each device may have either a metallic or a semi-conducting tube, the diodes were identified by gating with the substrate.

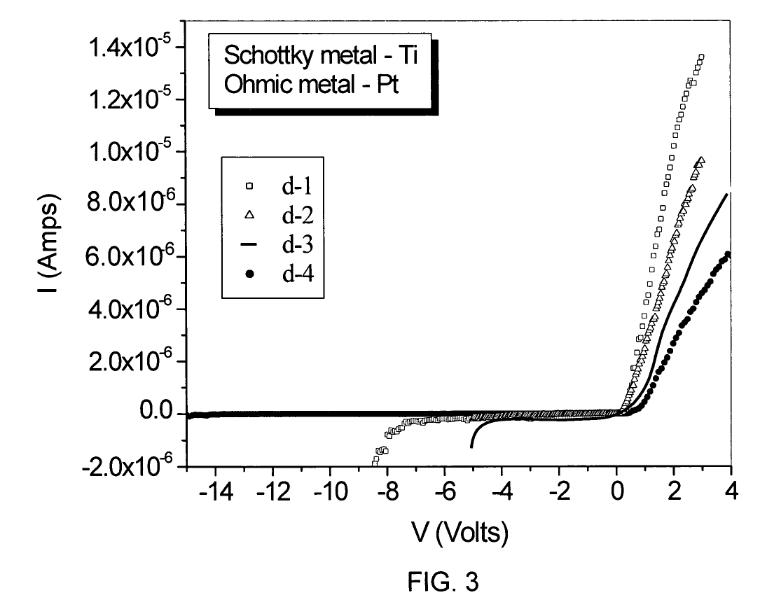

FIG. 3 shows rectifying current-voltage (Amp (I)-Volt (V)) characteristics of devices from this set with zero gate voltage. In contrast to conventional solid-state devices, it was noted that the s-SWNT devices (i.e., d-1, d-2, d-3, d-4) produced in the same batch on the same substrate showed significant variation in their DC-characteristics. This can be attributed to a combination of the nature of the tubes (varying tube diameter results in varying band gaps ˜0.3 eV to 0.6 eV, which, in turn, dictates the barrier height), their overall lengths, and the overlapping lengths with the two metal pads (the latter two quantities contribute to the overall device impedance). The diodes exhibited high current carrying capacity, in excess of 14 μA, high reverse bias breakdown voltages varying from −5 V to −15 V, very small leakage currents, in the range of <1 to ˜10 nano-Amps (nA), and high series resistances, in the range of 200 to 400 kilo-ohms (kΩ). These series resistances are, on the average, a factor of 50 larger than the lowest achievable DC resistance for a quantum confined geometry. This large series resistance is believed to be dominated by contact resistance. Using a phenomenological model, the kinetic inductance for the nanotubes was estimated to be ˜10 nH (given a 2.5 μm long nanotube). The phenomenological model was described by Burke, P. J., in Solid-State Electron, 2004, 48, 1981-1986.

These factors pose a significant challenge for impedance-matching in high-frequency applications. Effective impedance-matching requires decreasing both the individual tube impedance as well as the total device impedance. The former can be accomplished to a certain extent by annealing the contact pads, by improved wetting properties of the deposited metal, and by decreasing the lengths of the SWNTs (thus making it a ballistic transport device). The total device impedance can be decreased by using many nanotubes in parallel per device.

To illustrate this, a second set of devices was developed with multiple SWNTs in parallel per device. Each device typically had 8 to 10 SWNTs, of both metallic and semiconducting in nature, grown in parallel between the contact pads. The presence of m-SWNTs precludes rectification. Therefore, using a previously described procedure (i.e., Collins, P. G.; Arnold, M. S.; Avouris, P. Science, 2001, 292, 706-709), m-SWNTs (metallic tubes) were selectively burnt-out by gating off s-SWNTs by biasing the substrate to +20 V and increasing the total current through the device in a step-wise fashion. After every burn-out step, the I-V curves were recorded until a rectifying curve was observed.

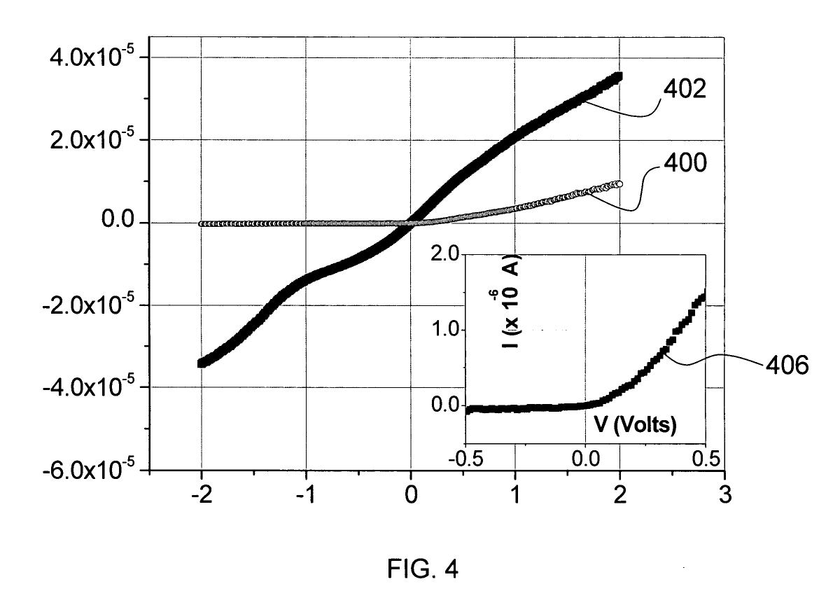

FIG. 4 shows the I-V curves for one such device before and after the selective burn-out. This procedure was successfully repeated on multiple devices. FIG. 4 shows the change in the characteristic from resistive 400 to rectifying 402 upon selective burn-out of the metallic SWNTs using the procedure described by Collins et al. The inset shows the rectified curve 406, by itself, in the low bias range.

The quality of a diode can be assessed by its ideality factor (n), calculated using the diode equation. Typically, this factor lies between one and two for good diodes with n=1 for an ideal diode. The value of n for the Schottky diodes was computed by fitting the curves using the following diode equation:

$$I = {I}_{S} \cdot [ {ⅇ}^{\frac{q \cdot ( V - {IR}_{s} )}{nkT}} - 1 ] , \qquad ( 1 )$$

where, I=the measured total current, V=corresponding anode-cathode biasing voltage, I_{S}=the reverse saturation current (or the leakage current), Rₛ=the lumped series resistance of the device (the effective total of the contact resistances and the nanotube resistance), q=the electron charge (1.602×10⁻¹⁹ columbs (C)), k=the Boltzmann constant, and T=the temperature (° K).

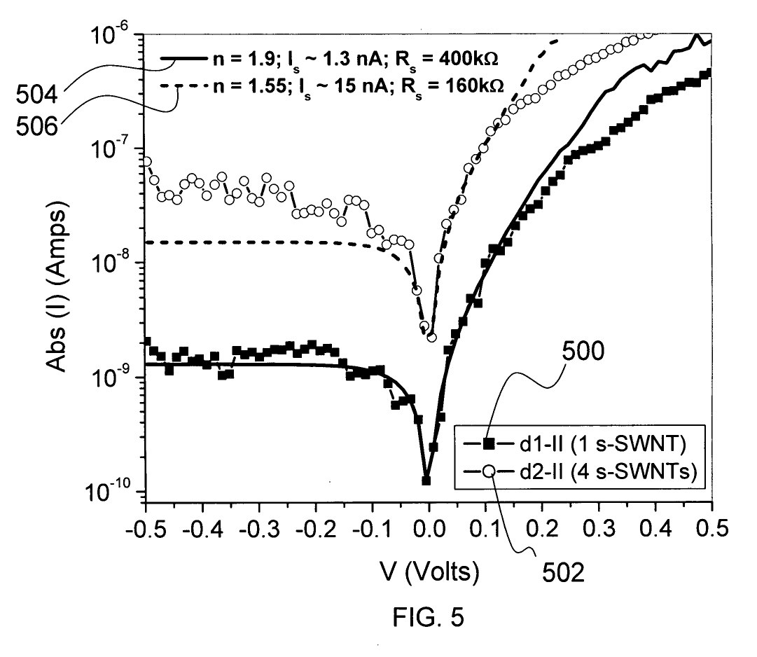

FIG. 5 shows plots of the absolute value of Amps (I) versus voltage (V) at room temperature for two diodes (i.e., d1-II (with single s-SWNT) 500 and d2-II (with multiple s-SWNTs) 502) along with corresponding curve fits (504 and 506 respectively) from equation (1). The curve shows the absolute magnitude of the current plotted against the corresponding voltage. The diode fits give n=1.5 to 1.9 and I_{S}=1.3 nA to 15 nA for the two diodes.

In low bias ranges (as shown in the FIG. 5), the ideality curve fits well, with n ranging from 1.5 to 1.9. The important observations are the lowering of the resistance from d1-II to d2-II, and the increase in leakage current from d1-II to d2-II. In d2-II, four s-SWNTs out of nine total SWNTs survived the burn-out process. The effective Rₛ of 160 kΩ, post burn-out, points to the fact that the individual SWNTs still suffer from high Rₛ because of the contact resistance (these contacts were not annealed to avoid potential Pt delamination problems). Additionally, the I_{S} increases in multiple s-SWNT devices because of the cumulative leakage effect. For the device d2-II, if the parasitic capacitances between the contact pads and the substrate are neglected (this assumption is valid using a substrate-less design as described by Gaidis et al.), and considering only the electrostatic capacitance of four nanotubes to the substrate (˜81 attofarad (aF) per tube) and the quantum capacitance (4C_{Q}˜970 aF per tube), which are in series, then the effective capacitance is C_{P}˜75 aF per tube (for a 2-nm diameter SWNT, 2.5-μm long). The Gaidis et al. reference is as follows: Gaidis, M. C.; Pickett, H. M.; Smith, C. D.; Smith, R. P.; Martin, S. C.; Siegel, P. H. IEEE Trans. Microwave Theory Tech., 2000, 48, 733-739.

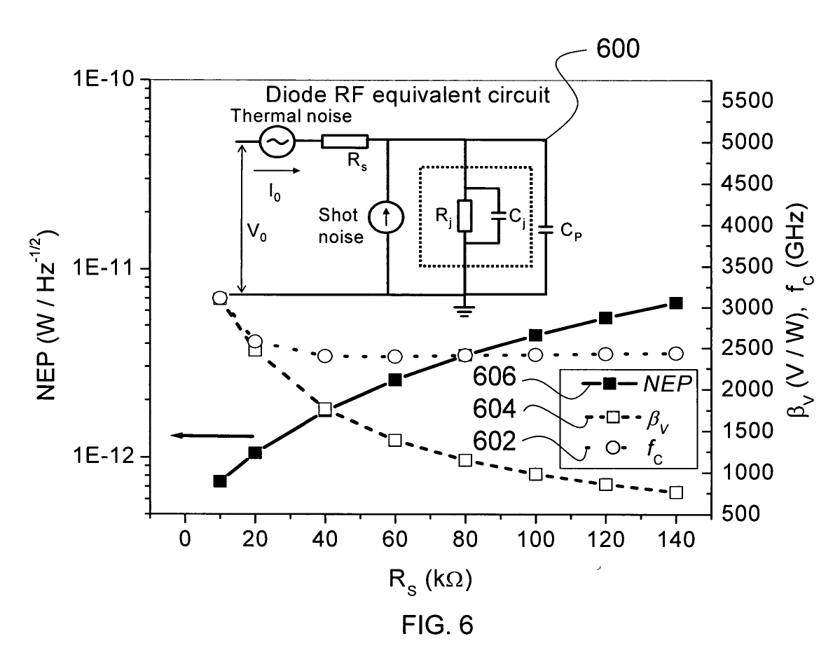

Using the Rₛ and the C_{P} parameters, the predicted performance of the d2-II SWNT-Schottky diode as a direct detector at high-frequency ranges during low bias operation was calculated. The analysis used a simplistic noise equivalent circuit 600 as shown in the inset of FIG. 6. The values were calculated for direct detection of a 2.5 THz frequency signal at room temperature. The inset 600 shows the diode RF equivalent circuit used in this model. In this analysis, the role of the inductance (L) of the system was neglected because of the high value of Rₛ and because it was assumed that L could be tuned out using external circuit elements. Three important performance parameters were estimated, which were, the cut-off frequency (f_{C}), the voltage responsivity (β_{V}), and the noise equivalent power (NEP). The cut-off frequency, f_{C}, gives the upper frequency limit of a device for an AC response, which directly relates to the device associated delay times. β_{V} is defined as the detector signal strength generated per unit input power of the AC signal (V/W) and the NEP is defined as input power required to bring the signal-to-noise ratio to unity in a unit video bandwidth (W/square-root (√) Hz). For high-frequency operation it is desirable to have high f_{C}, high β_{V}, and low NEP from a diode. In the performance analysis presented here, the responsivity and the NEP of the SWNT-Schottky diodes have been estimated for 2.5 THz frequency, which is a region of interest for space-borne applications (for example, the remote detection of oxygen and hydroxyl (OH) species whose characteristic emission lines are present at this frequency), using relations shown below.

These relations are based upon the circuit shown in the inset 600 of FIG. 6, in which, Rⱼ and Cⱼ refer to the diode's dynamic junction resistance and capacitance respectively. In the model used here, it is important to note that in low bias ranges, which is the operating region of concern of the diode, Rⱼ and C_{P} have the dominant influence on f_{C} (the effect of Cⱼ is negligibly small because of the nanotube area). The cut-off frequency (f_{C}) is calculated as:

$$\begin{matrix}{f}_{C} = \frac{1}{2 π {R}_{j} {C}_{P}} \sqrt{\frac{{R}_{s} + {R}_{j}}{{R}_{s}}} , \\ where & ( 2 ) \\ {R}_{j} = \frac{nkT}{q ( {I}_{0} + {I}_{S} )} . & ( 3 )\end{matrix}$$

In equation (2), the quantity under the square root tends to unity for Rₛ>>Rⱼ (which is true as long as Rₛ is in the range of hundreds of kΩ). In equation (3), I₀ is the DC bias current (same as I in equation (1)) corresponding to the optimized DC bias voltage, V₀. V₀ is calculated iteratively to achieve the least noise power for a given diode and a given detection frequency. V₀, in turn, depends on Rₛ. The voltage responsivity, β_{V}, is calculated as,
β_{V}=γ₀βR_{VT}(V/W), (4)
where

$${γ}_{0} = \frac{{R}_{j}}{( {R}_{s} + {R}_{j} ) [ 1 + {( f / {f}_{C} )}^{2} ]} ; β = \frac{q}{2 nkT} ;$$

and, R_{CT}=Rₛ+Rⱼ; assuming an infinite load and an antenna-matched source to the diode. The NEP is calculated by dividing the voltage noise density νₙ, by the voltage responsivity, β_{V}, according to the following:

$$NEP = \frac{{v}_{n}}{{β}_{V}} ( W \text{/} √ Hz ) , \\ where \\ {v}_{n} = \sqrt{4 {kT}_{D} {R}_{VT}} ( V \text{/} √ Hz ) , \qquad ( 5 )$$

T_{D} is the diode equivalent noise temperature. As Rₛ decreases, β_{V} increases at a higher rate than the rate of decrease of νₙ, thus effectively decreasing the NEP.

The above-mentioned performance parameters have been calculated for the device d2-II using the following values: Rₛ=640 kΩ/tube (for four tubes in parallel the effective Rₛ is 160 kΩ; in comparison, Rⱼ is only ˜796 Ω/tube); C_{P}=75 aF, n=1.55; and I_{S}=15 nA. For this device, it was found that the optimized bias voltage, V₀, is equal to 0.20 V, which is in a region where the ideality curve fit begins to deviate (see FIG. 5). For a realistic estimate, an operating bias of V₀=0.17 V was used, which is the maximum bias voltage where the curve fit still holds within reason. Therefore, for an operating bias voltage, V₀=0.17 V; β_{V(d2-II)}˜2.6 V/W; NEP_{(d2-II)}˜2.0×10⁻⁸ W/√Hz; and f_{C(d2-II)}˜0.54 THz. For comparison purposes, the same parameters were calculated for a gallium arsenic (GaAs) solid-state Schottky diode using the following values: Rₛ=20Ω; C_{P}=250 aF; n=1.3; and I_{S}=10 fA, thereby providing results of V₀=0.59 V (optimized for the SWNT-Schottky device); β_{V(GaAS)}˜4116 V/W; NEP_{(GaAs)}˜5.4×10⁻¹³ W/√Hz; and f_{C(GaAS)}˜7 THz. These results indicate that the predicted high-frequency performance of d2-II is quite poor compared to that of the state-of-the-art. This poor performance is caused predominantly by the high value of Rₛ, which indirectly decreases f_{C}, and directly brings down β_{V} and the NEP (this is easy to see as resistance is a source of thermal noise). In addition to this degradation in device performance at high frequencies, the high series resistance also introduces non-trivial concerns for impedance matching. To complete further illustrate this, changing the SWNT Schottky diode such that it contains at least 100 tubes of 2 nm diameter and 100 nm length in parallel, each tube with Rₛ=10 kΩ; C_{P}=3 aF; n=1.3 (similar to the GaAs device); and I_{S}=1 nA, provides values of V₀=0.17 V; β_{V}˜3105 V/W; NEP˜7.4×10⁻¹³ W/√Hz; and f_{C}˜3.1 THz. Such a device enjoys a much higher voltage responsivity and NEP (compared to that of d2-II) that are in a comparable range to that of the GaAs device (i.e., the cut-off frequency is lower because of the lower optimized biasing voltage). Except for the Rₛ, which is approaching the quantum limit (6.25 kΩ), all other assumed parameters are reasonably practical as explained herein. The hypothetical device has a significantly decreased C_{P} because of the assumed tube length that is shorter by a factor of 25 compared to that in d2-II. This results in a smaller electrostatic capacitance (˜3.24 aF) and hence a smaller overall capacitance (the in-series quantum capacitance is ˜38.8 aF, still too large to affect the overall C_{P}). The assumed value of n is also within reason as the device d2-II, which is much inferior compared to the hypothetical device, already has n of 1.55. Additionally, by decreasing Rₛ per tube (see Equation 1) of the device, the effective n is expected to improve at least partially. For the same hypothetical SWNT Schottky diode, FIG. 6 shows the trend of f_{C} 602, β_{V} 604, and the NEP 606 variation with respect to Rₛ (all calculations are performed at room temperature with V₀ optimized for the lowest NEP at 2.5 THz).

For high-frequency technological applications of carbon nanotubes, the results suggest that key impedances should be adjusted to improve device performance. It has been observed that the AC resistance in the SWNT device could become considerably lower because of the capacitive coupling between the nanotube and the contact pads. Such observations were made by Li, S; Yu, Z; Yen, S-F; Tang, W. C.; and Burke, P. J., in Nano Lett. 2004, 4, 753-756. In this case, it is indeed possible to bring Rₛ down to the order of a few kΩ, which then should improve the NEP. Also, growing hundreds of nanotubes in parallel per device allows the effective impedance (series resistance and the kinetic inductance) to be decreased to achieve proper impedance matching. To decrease parasitic capacitances, one can employ the substrate-less dielectric membrane design in which the substrate is relegated to just a frame to support the dielectric membrane upon which the device is fabricated. This is an attractive option for high-frequency applications that cannot be readily achieved in a field effect transistor (FET) design in which a gate is a necessity, either in the substrate form (bottom gate) or as a top gate. In essence, the SWNT Schottky diodes with multiple parallel tubes per device with individually reduced resistances to the order of a few kΩ promise superior performance compared to that of the state-of-the art solid-state Schottky diodes (particularly for applications at high frequencies).

What is claimed is:

1. A nanotube Schottky diode, comprising:
a nanotube formed of a semi-conductive material;
a first conductive contact attached with the nanotube; and
a second conductive contact attached with the nanotube, where the first conductive contact and the second conductive contact are formed of dissimilar materials and each of the conductive contacts is attached with the nanotube such that they are separated.

2. A Schottky diode as set forth in claim 1, wherein the first conductive contact is formed of a material that has a lower work function than that of the nanotube to form a Schottky contact and the second conductive contact is formed of a material that has a higher work function than that of the nanotube to form an Ohmic contact.

3. A Schottky diode as set forth in claim 2, further comprising a substrate with an insulating layer formed on the substrate, wherein the nanotube is attached with the insulating layer.

4. A Schottky diode as set forth in claim 3, wherein the nanotube has a length with two ends and the first conductive contact is attached proximate one of the two ends of the nanotube while the second conductive contact is attached proximate the other of the two ends of the nanotube.

5. A Schottky diode as set forth in claim 4, wherein the Schottky contact is formed of at least one material selected from a group consisting of titanium and aluminum, and wherein the Ohmic contact is formed of at least one material selected from a group consisting of platinum and palladium.

6. A Schottky diode as set forth in claim 5, wherein each of the conductive contacts further comprises a contact pad attached with the conductive contact.

7. A Schottky diode as set forth in claim 6, wherein the substrate is formed of silicon and the insulating layer is formed of at least one material selected from a group consisting of silicon dioxide and silicon nitride.

8. A Schottky diode as set forth in claim 7, wherein each of the conductive contacts includes an axis that is approximately parallel to the other axis and that runs approximately perpendicular to the nanotube, and wherein the substrate is etched-out as an etched-out portion between each of the axes, such that the insulating layer and the nanotube span across the etched-out portion.

9. A Schottky diode as set forth in claim 7, wherein each of the conductive contacts includes an axis that is approximately parallel to the other axis and that runs approximately perpendicular to the nanotube, and wherein a gap exists in the substrate and in the insulating layer between each of the axes, such that the nanotube is suspended across and bridges the gap.

10. A Schottky diode as set forth in claim 9, wherein the nanotube is a single-walled carbon nanotube.

11. A Schottky diode as set forth in claim 9, wherein the nanotube is a multi-walled carbon nanotube.

12. A Schottky diode as set forth in claim 8, wherein the nanotube is a single-walled carbon nanotube.

13. A Schottky diode as set forth in claim 8, wherein the nanotube is a multi-walled carbon nanotube.

14. A Schottky diode as set forth in claim 3, wherein each of the conductive contacts includes an axis that is approximately parallel to the other axis and that runs approximately perpendicular to the nanotube, and wherein the substrate is etched-out as an etched-out portion between each of the axes, such that the insulating layer and the nanotube span across the etched-out portion.

15. A Schottky diode as set forth in claim 3, wherein each of the conductive contacts includes an axis that is approximately parallel to the other axis and that runs approximately perpendicular to the nanotube, and wherein a gap exists in the substrate and in the insulating layer between each of the axes, such that the nanotube is suspended across and bridges the gap.

16. A Schottky diode as set forth in claim 2, wherein the Schottky contact is formed of a material selected from a group consisting of titanium and aluminum, and wherein the Ohmic contact is formed of a material selected from a group consisting of platinum and palladium.

17. A Schottky diode as set forth in claim 1, wherein the nanotube is a nanotube selected from a group consisting of a single-walled carbon nanotube and a multi-walled carbon nanotube.

18. A method for forming a nanotube Schottky diode, comprising acts of:
forming a nanotube of a semi-conducting material such that the nanotube has two ends;
attaching a first conductive contact to the nanotube proximate one of the two ends, wherein the first conductive contact is formed of a material that has a lower work function than that of the nanotube to form a Schottky contact; and
attaching a second conductive contact to the nanotube proximate the other of the two ends such that the two conductive contacts are seperated, where the second conductive contact is formed of a material that has a higher work function than that of the nanotube to form an Ohmic contact, thereby forming the nanotube Schottky diode.

19. A method for forming a nanotube Schottky diode as set forth in claim 18, wherein the act of forming the nanotube further comprises acts of:
patterning a catalyst onto an insulating layer;
growing the nanotube; and
wherein the acts of attaching a first conductive contact and a second conductive contact further comprises an act of depositing titanium and platinum as the Schottky and Ohmic contacts, respectively.

20. A method for forming a nanotube Schottky diode as set forth in claim 18, wherein each of the conductive contacts are formed such that they each include an axis that is approximately parallel to the other axis and that runs approximately perpendicular to the nanotube, and further comprising an act of etching out the substrate as an etched-out portion between each of the axes, such that the insulating layer and the nanotube span across the etched-out portion.

21. A method for forming a nanotube Schottky diode as set forth in claim 18, wherein each of the conductive contacts are formed such that they each include an axis that is approximately parallel to the other axis and that runs approximately perpendicular to the nanotube, and further comprising an act of forming the substrate and insulating layer such that a gap exists in the substrate and in the insulating layer between each of the axes, such that the nanotube is suspended across and bridges the gap.

22. A nanotube Schottky diode produced by the method of claim 18.

23. A nanotube Schottky diode produced by the method of claim 19.

24. A nanotube Schottky diode produced by the method of claim 20.

25. A nanotube Schottky diode produced by the method of claim 21.

26. A nanotube Schottky diode, comprising:
a substrate;
an insulating layer formed on the substrate;
a nanotube formed on the insulating layer, the nanotube being formed of a semi-conductive material;
a first conductive contact attached with the nanotube;
a second conductive contact attached with the nanotube, where the first conductive contact and the second conductive contact are formed of dissimilar materials and each of the conductive contacts is attached with the nanotube such that they are separated;
wherein the first conductive contact is formed of a material that has a lower work function than that of the nanotube to form a Schottky contact and the second conductive contact is formed of a material that has a higher work function than that of the nanotube to form an Ohmic contact;
wherein the Schottky contact is formed of a material selected from a group consisting of titanium and aluminum, and wherein the Ohmic contact is formed of a material selected from a group consisting of platinum and palladium; and
wherein each of the conductive contacts further comprises a contact pad attached with the conductive contact.
